(19) United States
(12) Patent Application Publication
(10) Pub. No.: US 2013/0025663 A1
(43) Pub. Date: Jan. 31, 2013

(54) INVERTED PYRAMID TEXTURE FORMATION ON SINGLE-CRYSTALLINE SILICON

(71) Applicants: Jun Liu, Irvington, NY (US); Qiang Huang, Croton on Hudson, NY (US); Young-hee Kim, Mohegan Lake, NY (US)

(72) Inventors: Jun Liu, Irvington, NY (US); Qiang Huang, Croton on Hudson, NY (US); Young-hee Kim, Mohegan Lake, NY (US)

(73) Assignee: INTERNATIONAL BUSINESS MACHINES CORPORATION, Armonk, NY (US)

(21) Appl. No.: 13/192,088

(22) Filed: Jul. 27, 2011

(51) Int. Cl. H01L 31/0236; H01L 31/18

(52) U.S. Cl. 136/256; 438/71; 257/E31.13

(57) ABSTRACT

A method for texturing a single-crystalline silicon substrate is provided in which inverted pyramids are formed within the textured single-crystalline silicon substrate. The textured single-crystalline silicon substrates containing the inverted pyramids provided by the present disclosure have a low reflectance associated therewith and thus can be used as a component of a silicon solar cell. The method includes forming a plurality of openings that extend beneath an upper surface of a single-crystalline silicon substrate, and forming inverted pyramids in each of the openings by expanding each opening.

The present disclosure relates to semiconductor manufacturing, and more particularly, to a method for texturing a single-crystalline silicon substrate. The present disclosure also relates to a textured single-crystalline silicon substrate having a random distribution of randomly sized inverted pyramids located therein.

A photovoltaic device is a device that converts the energy of incident photons to electromotive force (e.m.f.). Typical photovoltaic devices include solar cells, which are configured to convert the energy in the electromagnetic radiation from the Sun to electric energy.

In a typical solar cell, single-crystalline silicon is generally used as one of the components of the cell. In such applications, the single-crystalline silicon needs to have a non-planar surface to improve light capture. Typically, the non-planar surface has concave and convex patterns with a minute pyramid (i.e., square pyramid) shape. In such solar cells, the light reflected from one spot impinges again to another spot on the surface of the crystalline solar cell by virtue of the ‘textured’ surface, penetrating into the solar cell to be effectively absorbed in the solar cell. Although a portion of the impinging light that has not been fully absorbed, but arrives at the back face of the solar cell, is reflected back to the surface again, that portion of impinging light can be reflected again at the surface comprising steeply inclined pyramidal surfaces, thereby confining the light in the solar cell to improve absorption of light and to enhance power generation.

In conventional single-crystalline silicon solar cells, a textured structure including non-inverted pyramids is formed by immersing the exposed (100) face of a single-crystalline silicon wafer into a mixed solution prepared by adding 5 to 30% by volume of isopropyl alcohol into an aqueous solution of an alkaline, i.e., sodium hydroxide (NaOH) or potassium hydroxide (KOH), which may also include some added silicon. Etching in this mixed solution is performed at a temperature of from 70° C. to 95° C.

The etching rate in anisotropic etchants of the kind described above depends on the crystallographic orientation of the silicon surface being etched. The etching rate on the (111) face is significantly lower than the other crystallographic orientations. Accordingly, the (111) face with the slowest etching rate is advantageously left on the surface. Since this (111) face is inclined by about 54.7 degree against the (100) face, pyramidal projections constituted of the (111) face and its equivalent faces are formed. The non-inverted pyramid size and density depends on the KOH or NaOH concentration, the amount of added silicon already dissolved in the bath, and additive such as isopropyl alcohol.

Although prior art processes of forming textured silicon surface having non-inverted pyramids can be used to lower the reflectance of a single-crystalline silicon substrate, there is still a need to provide textured single-crystalline silicon substrates whose reflectance is even lower than that achieved utilizing prior art aqueous alkaline etchant solutions.

### SUMMARY

The present disclosure provides a method for texturing a single-crystalline silicon substrate in which inverted pyramids are formed within the textured single-crystalline silicon substrate. The textured single-crystalline silicon substrates containing the inverted pyramids provided by the present disclosure have a lower reflectance as compared to prior art single-crystalline silicon substrates that contain a non-inverted pyramid textured surface.

In some embodiments, the inverted pyramids provided in the present disclosure have a fixed size and are evenly distributed within the textured single-crystalline silicon substrate. In such an embodiment, a mask can be used in forming a plurality of evenly distributed and evenly sized openings within a single-crystalline silicon substrate. After forming the plurality of openings, the openings are expanded utilizing an anisotropic silicon etch.

In other embodiments, the inverted pyramids have a random size and are randomly distributed within the textured single-crystalline silicon substrate. In such an embodiment, a maskless approach can be used in forming a plurality of randomly distributed and randomly sized openings within a single-crystalline silicon substrate. After forming the plurality of openings, the openings are expanded utilizing an anisotropic silicon etch.

In one embodiment of the present disclosure, a method for texturing a crystalline silicon substrate is provided. The method includes forming a plurality of openings that extend beneath an upper surface of a single-crystalline silicon substrate. After forming the plurality of openings within the single-crystalline silicon substrate, inverted pyramids are formed by expanding the openings that were formed in the single-crystalline silicon substrate.

In another embodiment of the present disclosure, a method for texturing a crystalline silicon substrate is provided that includes forming a plurality of metal nanoparticles on an upper surface of a single-crystalline silicon substrate. A plurality of openings is then etched into the single-crystalline silicon substrate utilizing each of the plurality of metal nanoparticles as a catalyst. After forming the plurality of openings, the metal nanoparticles are removed from within each of the plurality of openings. Next, inverted pyramids are formed by expanding the openings that were formed in the single-crystalline silicon substrate.

In yet another embodiment, a semiconductor structure is provided that includes a textured single-crystalline silicon substrate having a plurality of inverted pyramids located beneath an upper surface of the single-crystalline silicon substrate. In accordance with one embodiment of the present disclosure, the inverted pyramids have a random size and are randomly distributed within the textured single-crystalline silicon substrate.

### BRIEF DESCRIPTION OF THE DRAWINGS

FIG. 1 is a pictorial representation (through a cross sectional view) illustrating a single-crystalline silicon substrate that can be employed in the present disclosure.

FIGS. 2A-2B are pictorial representations (through cross sectional views) illustrating the single-crystalline silicon substrate of FIG. 1 after forming openings within the single-crystalline silicon substrate in accordance with the present disclosure.

FIGS. 3A-3B are pictorial representations (through cross sectional views) illustrating the structure of FIGS. 2A-2B after inverted pyramid formation within the single-crystalline silicon substrate.

FIG. 4 is a pictorial representation (through a cross sectional view) illustrating the single-crystalline silicon substrate of FIG. 1 after forming metal nanoparticles on the surface thereof in accordance with a specific embodiment of the present disclosure.

FIG. 5 is a pictorial representation (through a cross sectional view) illustrating the structure of FIG. 4 after performing a metal nanoparticle catalyzed etching process.

FIG. 6 is a pictorial representation (through a cross sectional view) illustrating the structure of FIG. 5 after removing the metal nanoparticles from within openings that are formed by the metal nanoparticle catalyzed etching process.

FIG. 7 is a pictorial representation (through a cross sectional view) illustrating the structure of FIG. 6 after inverted pyramid formation within the single-crystalline silicon substrate.

FIG. 8 is a scanning electron microscopic (SEM) photograph at a magnification of 10.00 KX showing the formation of a random distribution of randomly sized Pt nanoparticles on an upper surface of a single-crystalline silicon substrate in accordance with the sole Example of the present disclosure.

FIG. 9 is a scanning electron microscopic (SEM) photograph at a magnification of 10.00 KX showing the formation of a plurality of randomly distributed and randomly sized openings beneath an upper surface of a single-crystalline silicon substrate in accordance with the sole Example of the present disclosure.

FIG. 10 is a scanning electron microscopic (SEM) photograph at a magnification of 10.00 KX showing the formation of a plurality of randomly distributed and randomly sized inverted pyramids within a single-crystalline silicon substrate in accordance with the sole Example of the present disclosure.

FIG. 11 is a plot of reflectance vs. wavelength (nm) for a textured single-crystalline silicon substrate prepared using the procedure described in the sole Example of the present disclosure, as compared to an as-cut single-crystalline silicon substrate and a textured single-crystalline silicon substrate with normal pyramids that was textured using a KOH etchant.

### DETAILED DESCRIPTION

The present disclosure, which provides a method for texturing a single-crystalline silicon substrate and a textured single-crystalline silicon substrate that includes a random distribution of randomly sized inverted pyramids, will now be described in greater detail by referring to the following discussion and drawings that accompany the present application. It is noted that the drawings are provided for illustrative purposes only and are not drawn to scale.

In the following description, numerous specific details are set forth, such as particular structures, components, materials, dimensions, processing steps and techniques, in order to illustrate the present disclosure. However, it will be appreciated by one of ordinary skill in the art that various embodiments of the present disclosure may be practiced without these, or with other, specific details. In other instances, well-known structures or processing steps have not been described in detail in order to avoid obscuring the various embodiments of the present disclosure.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

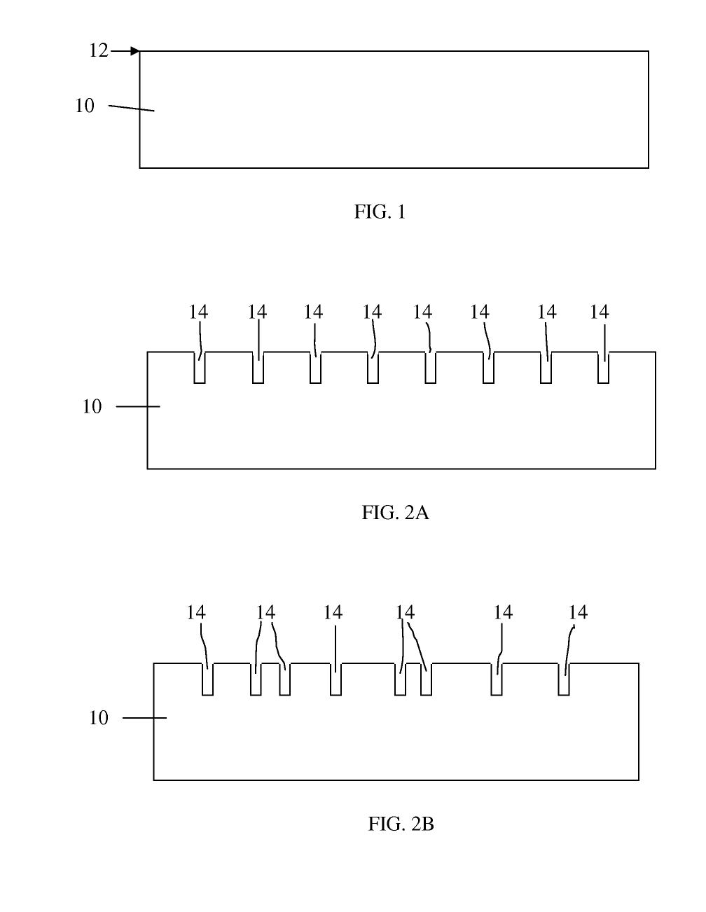

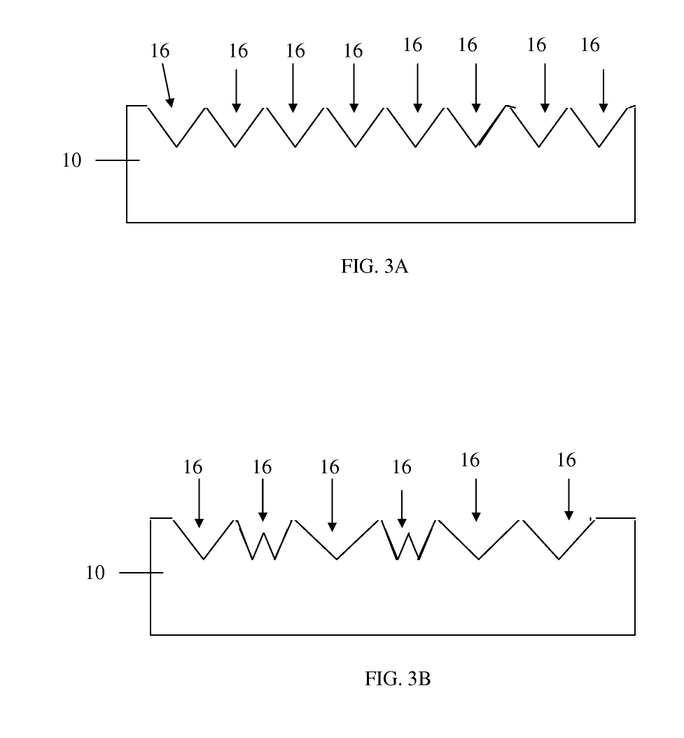

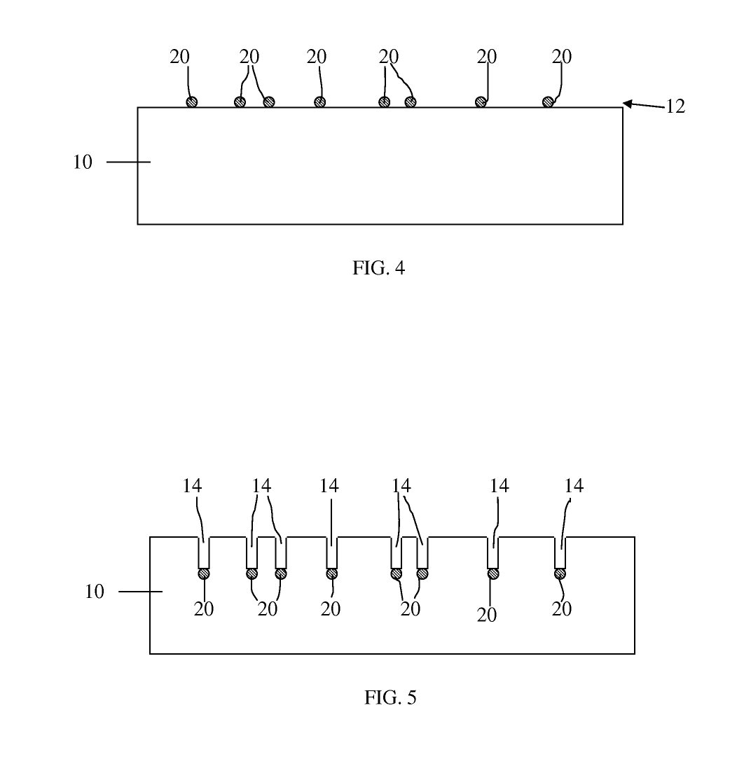

Reference is first made to FIGS. 1, 2A, 2B, 3A and 3B which illustrate a general method that can be used in the present disclosure to provide a textured single-crystalline silicon substrate having inverted pyramids located beneath an upper surface of the single-crystalline silicon substrate. Specifically, FIGS. 1, 2A, 2B, 3A and 3B illustrate a general method of the present disclosure which includes first providing a single-crystalline silicon substrate (FIG. 1), then forming openings within the single-crystalline silicon substrate (FIGS. 2A-2B), and thereafter forming inverted pyramids within the single-crystalline silicon substrate by expanding the openings (FIGS. 3A-3B).

In some embodiments in which a patterned mask is employed in forming the openings and/or forming the inverted pyramids, the openings and the inverted pyramids that are formed have a fixed size and fixed pattern within the single-crystalline silicon substrate. This embodiment is depicted in FIGS. 2A-3A. By “fixed pattern” it is meant that such a pattern is repeatable and pre-defined by a program or a mask. By “fixed size” it is meant that all the inverted pyramids in the same process have the same or similar size. In such an embodiment, the method of the present disclosure forms a textured single-crystalline substrate having a regular repeating pattern of evenly sized and spaced apart inverted pyramids.

In other embodiments in which no mask is employed in forming the openings and/or forming the inverted pyramids, the openings/inverted pyramids that are formed are randomly sized and are randomly distributed within the single-crystalline silicon substrate. This embodiment is depicted in FIGS. 2B-3B. By “randomly distributed” it is meant that the distribution of the inverted pyramids are not regular or repeated. By “randomly sized” it is meant that the sizes of the inverted pyramids are not the same and have a large range of distribution. In such an embodiment, the method of the present disclosure forms a textured single-crystalline substrate having a random distribution of randomly sized inverted pyramids formed therein.

Referring first to FIG. 1, there is illustrated a single crystalline silicon substrate 10 which has upper surface 12. The terms “single-crystalline or mono-crystalline silicon” denote any silicon substrate in which the crystal lattice of the entire substrate is continuous and unbroken to the edges of the substrate, with no grain boundaries.

The single-crystalline silicon substrate 10 can be fabricated using methods that are well known in the art. In one embodiment, the single-crystalline silicon substrate 10 can be formed by Czocharalski or other techniques using directional solidification. In another embodiment, the single-crystalline silicon substrate 10 can be a thin film that is grown on top of a substrate (for example, by epitaxial techniques).

In some embodiments, the single-crystalline silicon substrate 10 is non-doped. In other embodiments, the single-crystalline silicon substrate 10 is doped with either a p-type dopant or an n-type dopant. As used throughout the present application, “p-type” refers to the addition of impurities to an intrinsic semiconductor that creates deficiencies of valence electrons. Examples of p-type dopants, i.e., impurities, that can be present in single-crystalline silicon substrate 10 include, but are not limited to, boron, aluminum, gallium and indium. In one embodiment in which the crystalline silicon substrate 10 includes p-type dopant, the p-type dopant is present in a concentration ranging from 1×10⁹ atoms/cm³ to 1×10²⁰ atoms/cm³. In another embodiment in which the single-crystalline silicon substrate 10 includes a p-type dopant, the p-type dopant is present in a concentration ranging from 1×10¹⁴ atoms/cm³ to 1×10¹⁹ atoms/cm³. As used throughout the present application, “n-type” refers to the addition of impurities that contributes free electrons to an intrinsic semiconductor. Examples of n-type dopants, i.e., impurities, that can be present in the single-crystalline silicon substrate 10 include, but are not limited to, antimony, arsenic and phosphorous. In one embodiment in which the single-crystalline silicon substrate 10 includes an n-type dopant, the n-type dopant is present in a concentration ranging from 1×10⁹ atoms/cm³ to 1×10²⁰ atoms/cm³. In another embodiment in which the single-crystalline silicon substrate 10 includes an n-type dopant, the n-type dopant is present in a concentration ranging from 1×10¹⁴ atoms/cm³ to 1×10¹⁹ atoms/cm³.

In one embodiment, the single-crystalline silicon substrate 10 of FIG. 1 can be an element of any photovoltaic device, such as, for example, an element of a solar cell. In the case of solar cell applications, the single-crystalline silicon substrate 10 needs to have a non-planar surface to improve light capture within the single-crystalline crystalline silicon substrate 10.

Referring to FIGS. 2A-2B, there is illustrated the structure of FIG. 1 after forming openings 14 in the single-crystalline silicon substrate 10. As shown, each opening 14 extends beneath the upper surface 12 of the single-crystalline silicon substrate 10. In some embodiments and as shown in FIG. 2A, the openings 14 that are formed within the single-crystalline silicon substrate 10 have a fixed pattern and a fixed size. While in other embodiments, and as shown in FIG. 2B, the openings that are formed are randomly distributed and are randomly sized within the single-crystalline silicon substrate 10.

In one embodiment, the openings 14 that are formed within the single-crystalline silicon substrate 10 can be formed utilizing a mechanical scriber. The mechanical scriber that can be employed in the present disclosure includes any tool that has a sharp point on at least one end that can create an opening within a single crystalline silicon substrate 10.

In another embodiment, the openings 14 that are formed within the single-crystalline silicon substrate 10 can be formed utilizing a laser. Any laser can be used in the present disclosure so long as the laser is capable of forming an opening or creating defects within the single-crystalline silicon substrate 10. Suitable lasers that can be employed in the present disclosure in forming the openings 14 within the single-crystalline silicon substrate 10 include, but are not limited to, excimer lasers such as, for example, KrF or XeF, and solid state lasers, such as, for example, Nd:YAG.

In yet another embodiment, a reactive ion etching process can be used in forming the openings 14 within the single-crystalline silicon substrate 10. Any reactive ion etching process can be used in the present disclosure so long as the reactive ion etching process, i.e., etch chemistry, is capable of forming an opening or creating defects within the single-crystalline silicon substrate 10. Suitable reactive ion etching processes that can be employed in the present disclosure in forming the openings 14 within the single-crystalline silicon substrate 10 include, but are not limited to, SF₆/O₂. In some embodiments, a patterned mask can be applied atop the single-crystal silicon substrate 10 prior to forming the openings 14 utilizing a reactive ion etching. In other embodiments, no mask is employed in forming the openings 14 utilizing a reactive ion etching.

When a patterned mask is employed during the reactive ion etching, the patterned mask can be of any material that is more resistive to the reactive ion etching than silicon. Alternatively, the patterned mask can be any material that can not be etched by the reactive ion. The patterned mask can be formed utilizing lithography and etching. Notwithstanding the type of material that is employed as the patterned mask, the patterned mask has a plurality of openings therein which can be used in forming openings 14 within the single-crystalline silicon substrate 10.

In a further embodiment of the present disclosure, which is described in more detail herein below and further illustrated in FIGS. 5-7, a metal-catalyzed selective chemical etching process is used in forming the openings 14 within the single-crystalline silicon substrate 10. In some embodiments, a patterned mask can be applied atop the single-crystal silicon substrate 10 either before or after metal deposition, but prior to forming the openings 14 utilizing a metal-catalyzed selective chemical etching process. In other embodiments, no mask is employed in forming the openings 14 utilizing a metal-catalyzed selective chemical etching process.

When a patterned mask is employed during the selective chemical etching, the patterned mask can be of any material that does not react with the etchant or catalyze the reaction between the etchant and silicon. The patterned mask can be formed utilizing lithography and etching. Notwithstanding the type of material that is employed as the patterned mask, the patterned mask has a plurality of openings therein which can be used in forming openings 14 within the single-crystalline silicon substrate 10.

The depth of each opening 14 that is formed within the single-crystalline silicon substrate 10 may vary depending on the technique that was employed in forming the same. Typically, the depth of each opening 14 that is formed within the single-crystalline silicon substrate 10, as measured from the upper surface 12 of the substrate 10, is from 100 nm to 30 μm, with a depth from 500 nm to 15 μm being more typical.

Each opening 14 that is formed at this point of the present disclosure has a first width (w₁) located at the upper surface of the single-crystalline silicon substrate 12. The size of the first width (w₁) that is formed at this point of the present disclosure may vary depending on the technique that was employed in forming the same. Typically, the first width (w₁) of each of the openings that is formed at this point of the present disclosure is from 10 nm to 20 μm, with a first width (w₁) from 30 nm to 5 μm being more typical. The remaining width of each opening 14 that is beneath w₁ may tapper somewhat from the value of w₁.

Next, and as shown in FIGS. 3A-3B, inverted pyramids 16 are formed into the single-crystalline silicon substrate 10 by expanding the width of each of the openings 14. In some embodiments and as shown in FIG. 3A, the inverted pyramids 16 have a fixed pattern and a fixed size within the single-crystalline silicon substrate 10. In other embodiments and as shown in FIG. 3B, the inverted pyramids 16 are randomly sized and have a random distribution within the single-crystalline silicon substrate 10.

Inverted pyramids 16 that are formed in the present disclosure have a second width (w₂) located at the upper surface 12 of the single-crystalline silicon substrate 12 that is greater than the first width (w₁). Typically, the second width (w₂) of each of the inverted pyramids that is formed at this point of the present disclosure is from 100 nm to 30 μm, with a second width (w₂) from 500 nm to 15 μm being more typical.

Each inverted pyramid 16 has a base that is located at, or near the upper surface 12 of the single-crystalline silicon substrate 10 and an apex, that is located beneath the base and thus beneath the upper surface 12 of the single-crystalline silicon substrate 10.

The expanding of each of the openings 14 can be performed using an anisotropic silicon etch which has a different etch rate for removing certain planes of silicon relative to other planes of silicon. The anisotropic silicon etch employed in the present disclosure may include, but not limited to, potassium hydroxide (KOH), sodium hydroxide (NaOH), chlorine hydroxide, tetramethylammonium hydroxide (TMAH) or tetraethylammonium hydroxide (TEOH) as a wet chemical etchant.

In one embodiment, the anisotropic silicon etch that is employed in expanding each of the openings 14 can be performed at room temperature (i.e., a temperature from 20° C.-40° C.). In some embodiments, the anisotropic silicon etch that is employed in expanding each of the openings 14 can be performed at a temperature of less than room temperature. For example, and in some embodiments, the less than room temperature anisotropic silicon etch that is employed in expanding each of the openings 14 can be performed at a temperature within the range from 1° C. to 19° C. In other embodiments, the anisotropic silicon etch that is employed in expanding each of the openings 14 can be performed at a temperature that is greater than room temperature. For example, and in some embodiments, the greater than room temperature anisotropic silicon etch that is employed in expanding each of the openings 14 can be performed at a temperature within a range from 41° C. to 95° C. In yet another embodiment, the anisotropic silicon etch that is employed in expanding each of the openings 14 can be performed within any combination of the ranges mentioned above.

In one embodiment of the present disclosure, the textured crystalline silicon substrate has a weighted average reflectance between 400 nm to 1100 nm of from 0.02 to 0.20. In another embodiment of the present disclosure, the textured crystalline silicon substrate has a weighted average reflectance between 400 nm to 1100 nm of from 0.05 to 0.12. The term “weighted average reflectance” is used throughout the present application to denote the average reflectance weighted to the photon flux density of an AM 1.5 G spectrum. The weighted average reflectance can be determined by reflectance spectroscopy.

Reference is now made to FIGS. 4-7 which illustrate the basic processing steps that can be employed in one embodiment of the present disclosure in which a metal-catalyzed selective chemical etching process is employed. Although the drawings and description that follows represents a maskless approach for forming a random distribution of randomly sized inverted pyramids within a silicon-crystalline silicon substrate, the following embodiment can also be used with a mask to form an evenly distribution of inverted pyramids having a fixed size within the textured single-crystalline silicon substrate.

Referring first to FIG. 4, there is illustrated the single-crystalline silicon substrate 10 of FIG. 1 after forming metal nanoparticles 20 on an upper surface 12 of the substrate 10. The term “metal nanoparticles” is used throughout the present disclosure to denote metal particles that have a particle size that is below 2500 nm. In one embodiment, the metal nanoparticles 20 have a particle size from 10 nm to 1000 nm. In another embodiment, the metal nanoparticles 20 have a particle size from 30 nm to 200 nm.

In one embodiment of the present disclosure, the metal nanoparticles 20 can be formed by electroless plating. Electroless plating is a chemical oxidation-reduction process which depends upon the reduction process of metal ions in an aqueous solution containing a metal salt and the subsequent deposition of a metal while dissolving of silicon oxide from the oxidation of silicon without the use of electrical energy.

In another embodiment of the present disclosure, the metal nanoparticles 20 can be formed by electroplating. Electroplating, i.e., electrodeposition, is a plating process in which metal ions in a solution are moved by an electric field to coat an electrode. The process uses electrical current to reduce cations of a desired material from a solution and coat a conductive object with a thin layer of the material, such as a metal. In electrodeposition, i.e., electroplating, the part to be plated is the cathode of the circuit. In the current disclosure, the exposed upper surface of the single-crystalline silicon substrate 10 is employed as the cathode of the circuit. The anode that is employed in the electroplating process may or may not be made of the same metal as to be plated. The part to be plated, i.e., the single-crystalline silicon substrate 10, can be immersed, completely or in part, in an electroplating bath (e.g., an electrolyte) containing an anode, one or more dissolved metal salts as other ions that permit the flow of electricity. A power supply supplies a direct current to the anode and plating occurs at the cathode (i.e., the exposed surface of the single-crystalline silicon substrate 10).

In yet another embodiment of the present disclosure, the metal nanoparticles 20 can be formed by chemical vapor deposition. In the present disclosure, chemical vapor deposition is a chemical process in which the single-crystalline silicon substrate 10 is exposed to one or more volatile metal precursors, which react and/or decompose on the substrate surface to produce the metal nanoparticles.

In a further embodiment of the present disclosure, the metal nanoparticles 20 can be formed by physical vapor deposition. In the present disclosure, physical vapor deposition includes physical processes such as evaporation or sputtering from a metal source material rather than involving a chemical reaction at the surface of the single-crystalline silicon substrate 10.

In a yet further embodiment of the present disclosure, the metal nanoparticles 20 can be formed by spin coating. In the present disclosure, spin coating includes placing an excess amount of a solution or a suspension or a sol-gel including metal nanoparticles on a surface of the single-crystalline silicon substrate 10. The substrate including the excess solution or suspension or sol-gel is then rotated at a high speed in order to spread the fluid by centrifugal force.

In an even further embodiment, the metal nanoparticles 20 can be formed by drop casting or printing using the same chemicals as for the spin coating method.

The metal nanoparticles 20, which serve as a catalyst in forming openings within the silicon-crystalline silicon substrate 10, can be comprised of Pt, Ag, Au, Pd, Rh, Ru, Ir, Os, Mo or Ni. In some embodiments, alloys including at least two of the aforementioned metals can be employed as the metal nanoparticles. In one embodiment of the present disclosure, the metal nanoparticles 20 are comprised of Pt.

Referring to FIG. 5, there is illustrated the structure of FIG. 4 after performing a metal nanoparticle catalyzed etching process which forms a plurality of random distributed openings 14 within the single-crystalline silicon substrate 10.

In one embodiment, the metal nanoparticle catalyzed etching process includes an etchant that includes at least one fluoride-containing chemical that dissolves silicon oxide such as, but not limited to, HF, NH₄F, NaF, or KF, and as least one oxidant such as, but not limited to, H₂O₂, Fe(NO₃)₃, K₂Cr₂O₇, KMnO₄, Na₂S₂O₈ or KBrO₃. In one embodiment of the present disclosure, the metal nanoparticle catalyzed etching process can be performed at room temperature (i.e., a temperature from 20° C.-40° C.). In some embodiments, the metal nanoparticle catalyzed etching process can be performed at a temperature of less than room temperature. For example, and in some embodiments, the less than room temperature metal nanoparticle catalyzed etching process can be performed at a temperature within the range from 1° C. to 19° C. In other embodiments, the metal nanoparticle catalyzed etching process can be performed at a temperature that is greater than room temperature. For example, and in some embodiments, the greater than room temperature metal nanoparticle catalyzed etching process can be performed at a temperature within a range from 41° C. to 95° C. In yet another embodiment, the metal nanoparticle catalyzed etching process can be performed within any combination of the ranges mentioned above.

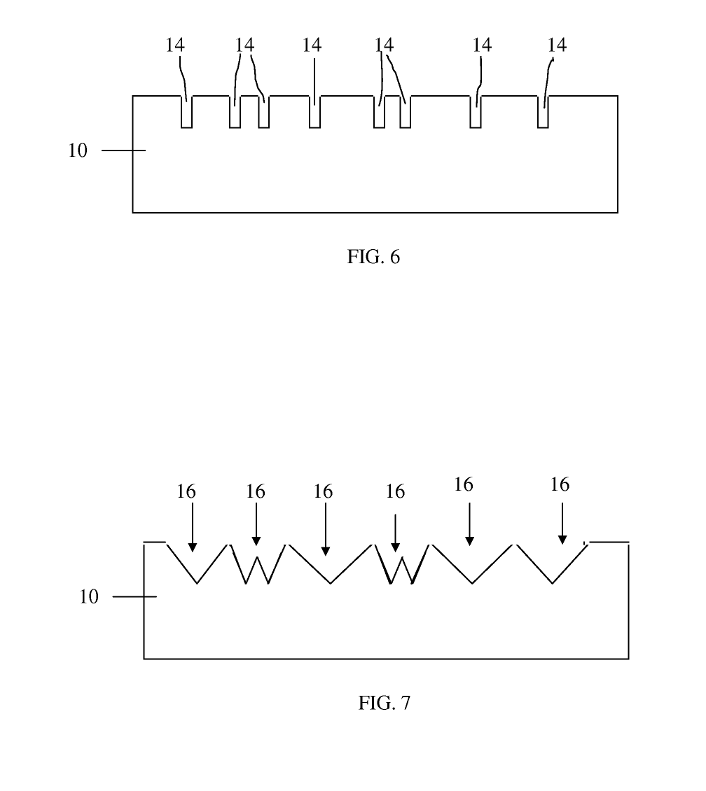

Referring to FIG. 6, there is illustrated the structure of FIG. 5 after removing the metal nanoparticles 20 from within each of the openings 14. In one embodiment, of the present disclosure, the metal nanoparticles 20 are removed from within each of the openings 14 utilizing an etchant solution that includes HCl, HNO₃, H₂Cr₂O₇, H₂CrO₄, H₂CrO₃, citric acid, H₂SO₄ or H₂O₂. In one embodiment, the etchant solution used in removing the metal nanoparticles from within each of the openings 14 comprises a solution of HCl:HNO₃:H₂O. In another embodiment of the present disclosure, the metal nanoparticles 20 can be removed from within each of the openings 14 at room temperature (i.e., a temperature from 20° C.-40° C.). In some embodiments, the metal nanoparticles 20 can be removed from within each of the openings 14 at a temperature of less than room temperature. For example, and in some embodiments, the less than room temperature metal nanoparticles 20 removal process can be performed at a temperature within the range from 1° C. to 19° C. In other embodiments, the metal nanoparticles 20 can be removed from within each of the openings 14 at a temperature that is greater than room temperature. For example, and in some embodiments, the greater than room temperature metal nanoparticles 20 removal can be performed at a temperature within a range from 41° C. to 95° C. In yet another embodiment, the metal nanoparticles 20 removal process can be performed within any combinations of the ranges mentioned above.

Referring to FIG. 7, there is illustrated the structure of FIG. 6 after inverted pyramid 16 formation within the single-crystalline silicon substrate 10. In this embodiment, the inverted pyramids 16 have a random size and are randomly distributed within the single-crystalline silicon substrate 10. The inverted pyramids 16 are formed by expanding the openings 14 that are formed utilizing an anisotropic silicon etching process as described above.

The following example is provided to illustrate an embodiment of the present disclosure and to also illustrate some advantages that can be achieved therefrom.

### EXAMPLE

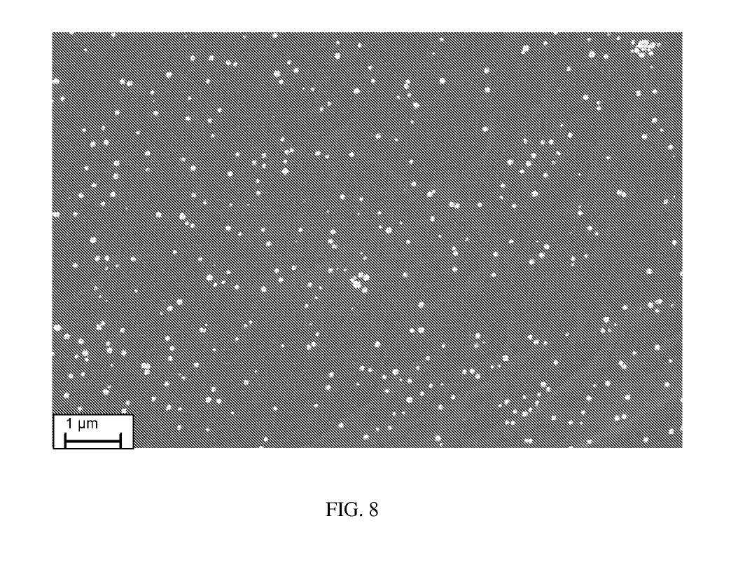

In this example, a single-crystalline silicon substrate is textured utilizing a metal-catalyzed selective chemical etching process in accordance with an embodiment of the present disclosure. Specifically, Pt nanoparticles were first formed on an upper surface of a single-crystalline silicon substrate utilizing electrodeposited and a bath comprising 0.2 mM K₂PtCl₄, 0.1 M H₂SO₄, and 3 M HF. The plating was carried out at room temperature by immersing the Si wafer into the deposition solution for 2 min. FIG. 8 is a scanning electron microscopic (SEM) photograph at a magnification of 10.00 KX showing the formation of a random distribution of randomly sized Pt nanoparticles on an upper surface of a single-crystalline silicon substrate in accordance with the sole Example of the present disclosure.

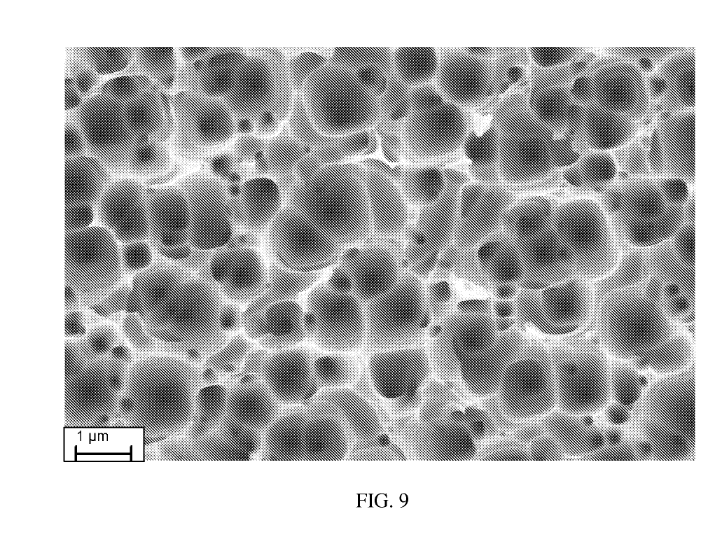

Next, a random distribution of different sized openings were formed into the single-crystalline silicon substrate utilizing each Pt nanoparticle as a catalyst. In particular, the openings were formed by etching with the mixture of HF and H₂O₂. FIG. 9 is a scanning electron microscopic (SEM) photograph at a magnification of 10.00 KX showing the formation of a plurality of random distributed and randomly sized openings beneath an upper surface of a single-crystalline silicon substrate in accordance with the sole Example of the present disclosure.

After forming the openings, the Pt nanoparticles that are present within the openings were removed utilizing an etchant solution comprising HCl:HNO₃:H₂O (8:1:1 ratio). The removal was performed at room temperature for about 1 minute.

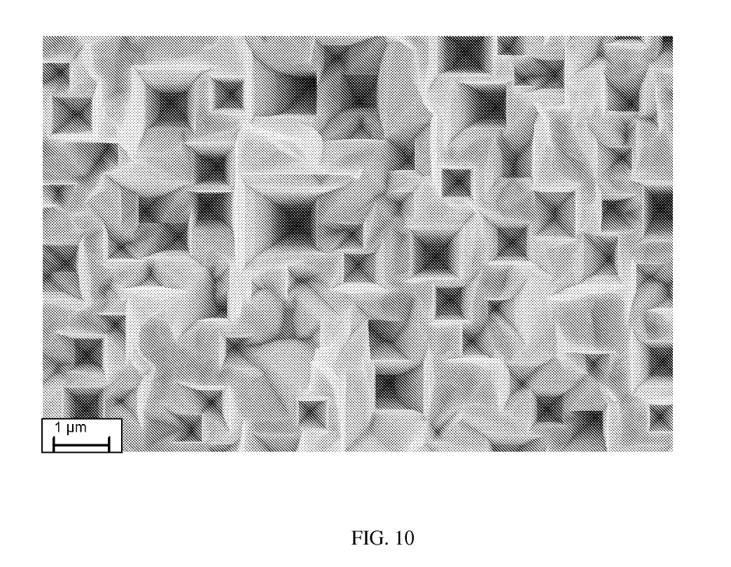

After removing the Pt nanoparticles from within the openings, inverted pyramids that were randomly distributed and of random size were formed by expanding the openings by utilizing an anisotropic silicon etching process. Specifically, the anisotropic silicon etching process that was employed in expanding the openings and thus forming the inverted pyramids within the single-crystalline silicon substrate included first removing any surface oxide from the substrate by dipping the same in a 10:1 DHF solution for approximately 2 minutes. After the DHF treatment, the substrate was dipped in a 1.5% KOH bath including 5% isopropyl alcohol. This KOH dipping was performed at room temperature for approximately 10 minutes. FIG. 10 is a scanning electron microscopic (SEM) photograph at a magnification of 10.00 KX showing the formation of a plurality of random distributed inverted pyramids within a single-crystalline silicon substrate in accordance with the sole Example of the present disclosure.

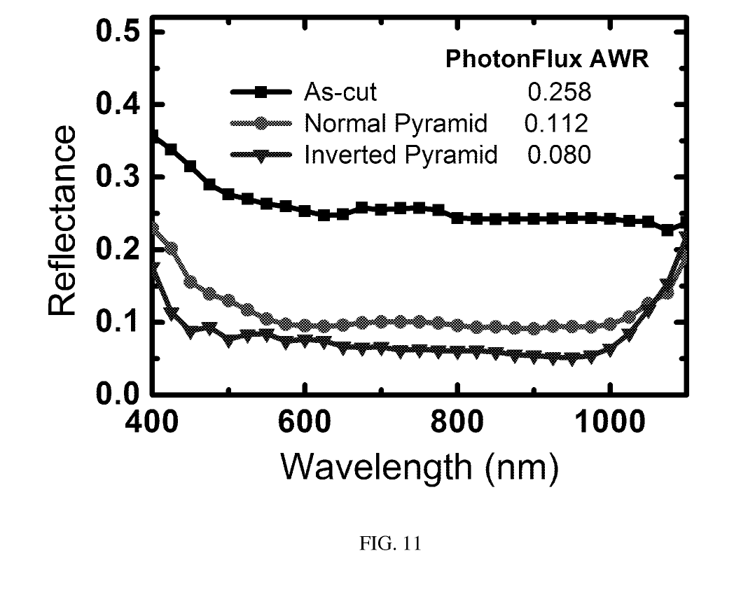

Reference is now made to FIG. 11 which is a plot of reflectance vs. wavelength (nm) for a textured single-crystalline silicon substrate prepared using the procedure described above, as compared to an as-cut single-crystalline silicon substrate (i.e., a non-textured substrate) and a textured single-crystalline silicon substrate with normal pyramids that was textured using a KOH etchant. From this plot the weighted average reflectance (WAR) of each substrate was determined. Specifically, the single-crystalline silicon substrate that was textured utilizing the metal-catalyzed selective chemical etching process described above had a WAR value of 0.080, the as-cut single-crystalline silicon substrate had a WAR value of 0.258, and the textured single-crystalline silicon substrate with normal pyramids that was textured using a KOH etchant had a WAR value of 0.112. This data illustrates that the single-crystalline silicon substrates that are textured utilizing an embodiment of the present disclosure have a lower reflectance as compared to a non-textured substrate or a substrate that was textured with a prior art process.

While the present disclosure has been particularly shown and described with respect to various embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

What is claimed is:

1. A method for texturing a crystalline silicon substrate comprising:
forming a plurality of openings that extend beneath an upper surface of a single-crystalline silicon substrate; and
forming inverted pyramids in each of said openings by expanding each of said openings.

2. The method of claim 1, wherein said forming the plurality of openings comprises utilizing a mechanical scriber.

3. The method of claim 1, wherein said forming the plurality of openings comprises utilizing a laser.

4. The method of claim 1, wherein said forming the plurality of openings comprises utilizing reactive-ion etching.

5. The method of claim 1, wherein said forming the plurality of openings comprises utilizing metal-catalyzed selective chemical etching.

6. The method of claim 1, wherein said forming the inverted pyramids comprises an anisotropic silicon etch.

7. The method of claim 6, wherein said anisotropic silicon etch comprises contacting with potassium hydroxide, sodium hydroxide, chlorine hydroxide, tetramethylammonium hydroxide or tetraethylammonium hydroxide.

8. The method of claim 1, wherein said forming the plurality of openings comprises a maskless process.

9. A method for texturing a crystalline silicon substrate comprising:
forming a plurality of metal nanoparticles on an upper surface of a single-crystalline silicon substrate;
etching a plurality of openings into said single-crystalline silicon substrate utilizing each of said plurality of metal nanoparticles as a catalyst;
removing each of the metal nanoparticles from within each of the plurality of openings; and
forming inverted pyramids in each of said openings by expanding each of said openings.

10. The method of claim 9, wherein said forming the plurality of metal nanoparticles comprises electroless plating, electroplating, physical vapor deposition, chemical vapor deposition, spin-coating, drop casting, or printing.

11. The method of claim 9, wherein said forming the plurality of metal nanoparticles comprises selecting at least one of Pt, Ag, Au, Pd, Rh, Ru, Ir, Os, Mo and Ni.

12. The method of claim 9, wherein said forming the plurality of metal nanoparticles comprises a maskless process.

13. The method of claim 9, wherein said etching the plurality of openings comprises contacting with an etchant comprising a fluoride-containing chemical.

14. The method of claim 13, wherein said etchant further comprising H₂O₂, Fe(NO₃)₃, K₂Cr₂O₇, KMnO₄, Na₂S₂O₈ or KBrO₃ as an oxidant.

15. The method of claim 9, wherein said removing each of the metal nanoparticles from within each of the of the plurality of openings comprises contacting with an etching solution comprising HCl, HNO₃, H₂Cr₂O₇, H₂CrO₄, H₂CrO₃, citric acid, H₂SO₄ or H₂O₂.

16. The method of claim 9, wherein said etching the plurality of openings comprises a maskless process.

17. The method of claim 9, wherein said forming the inverted pyramids comprises an anisotropic silicon etch.

18. The method of claim 9, wherein said anisotropic silicon etch comprises contacting with potassium hydroxide, sodium hydroxide, chlorine hydroxide, tetramethylammonium hydroxide or tetraethylammonium hydroxide.

19. A semiconductor structure comprising:
a textured single-crystalline silicon substrate having a plurality of inverted pyramids located beneath an upper surface of said single-crystalline silicon substrate, wherein said plurality of inverted pyramids have a random size and are randomly distributed within said textured single-crystalline silicon substrate.

20. The semiconductor structure of claim 19, wherein said textured single-crystalline silicon substrate is a component of a solar cell.

21. The semiconductor structure of claim 19, wherein each inverted pyramid of said a plurality of inverted pyramids has an apex and a base, wherein said apex is located inwardly of said base and said base is located at or near said upper surface of said single-crystalline silicon substrate.

22. The semiconductor structure of claim 21, wherein each of said inverted pyramids has a width from 100 nm to 30 μm.
